(19) United States
(12) Patent Application Publication
(10) Pub. No.: US 2011/0206590 A1
(43) Pub. Date: Aug. 25, 2011

(54) SILICON OXIDE FILM, METHOD FOR FORMING SILICON OXIDE FILM, AND PLASMA CVD APPARATUS

(75) Inventors: Minoru Honda, Hyogo (JP); Toshio Nakanishi, Hyogo (JP); Masayuki Kohno, Hyogo (JP); Junya Miyahara, Hyogo (JP)

(73) Assignee: TOKYO ELECTRON LIMITED, Tokyo (JP)

(21) Appl. No.: 13/121,598

(22) PCT Filed: Sep. 30, 2009
(86) PCT No.: PCT/JP2009/067440

§ 371 Date: Apr. 15, 2011

(30) Foreign Application Priority Data
Sep. 30, 2008 (JP) 2008-253936

(51) Int. Cl. C23C 16/40; C23C 16/34; C23C 16/455; C23C 16/511; C23C 16/52; C01B 33/12

(52) U.S. Cl. 423/335; 427/575; 118/723 AN

(57) ABSTRACT

To form a dense high-quality silicon oxide film (SiO₂ film or SiON film) having excellent insulating properties and an etching rate below or equal to 0.11 nm/s when using a 0.5% dilute hydrofluoric acid solution, plasma CVD is performed by setting a pressure within the processing container in the range from 0.1 Pa to 6.7 Pa. and using a process gas containing an SiCl₄ gas or an Si₂H₆ gas, and an oxygen gas, in a plasma CVD apparatus in which plasma is generated by introducing microwaves into a processing container through a planar antenna having a plurality of holes.

### TECHNICAL FIELD

The present invention relates to a silicon oxide film, a method for forming the silicon oxide film, a computer readable recording medium used for the method, and a plasma CVD apparatus.

### BACKGROUND ART

Currently, a thermal oxidation method, a plasma oxidation method, etc. that perform an oxidation process on silicon are known as methods of forming a high quality silicon oxide film (SiO₂ film or SiON film) having high insulating properties. However, when a multilayer insulation film is formed, the oxidation process cannot be performed, and it is required that is the multilayer insulation film is formed by depositing a silicon oxide film by using a CVD (Chemical Vapor Deposition) method. In order to form a silicon oxide film having high insulating properties by using a CVD method, a high temperature process at a temperature from 600° C. to 900° C. is required. Thus, there are problems that a device may be adversely affected due to increase of a thermal budget, and moreover, several restrictions may be generated when the device is manufactured.

Meanwhile, a plasma CVD method may be performed at a temperature around 500° C., but in this case, there is a problem that charging damage may be generated due to plasma having a high electron temperature (for example, Patent Document 1).

Accompanied by minuteness of a recent semiconductor device, a gate insulation film of, for example, a transistor, a flash memory device, or the like strongly requires two characteristics, i.e., a thickness as small as possible, and leak current generation as low as possible without electric characteristic deterioration even when stress is repeatedly applied. It has been difficult to form a film which satisfies these two requirements at the same time by a film-forming method using conventional plasma CVD. Accordingly, a technology of forming a high quality silicon oxide film having high insulating properties by using a plasma CVD method is not yet established.
(Patent Document 1) Japanese Laid-Open Patent Publication No. hei 10-125669

### DISCLOSURE OF THE INVENTION

### Technical Problem

To address the above problems, the present invention provides a method for forming a high-quality silicon oxide film having dense structure and high insulating properties by using a plasma CVD method.

### Technical Solution

According to an aspect of the present invention, there is provided a method for forming a silicon oxide film that has an etching rate below or equal to 0.11 nm/s when a 0.5% dilute hydrofluoric acid solution is used, on a substrate by using a plasma CVD is method, the method including: disposing the substrate in a processing container; supplying a process gas including a silicon containing gas and an oxygen containing gas into the processing container; setting an inside pressure of the processing container in a range from 0.1 Pa to 6.7 Pa; and generating a plasma of the process gas by introducing microwaves into the processing container through a planar antenna having a plurality of slots, and forming the silicon oxide film on the substrate by using the plasma.

The forming of the silicon oxide film may be performed by setting a temperature of a holding stage on which the substrate is placed in the processing container within the range from 300° C. to 600° C.

A flow ratio of the silicon containing gas to the entire process gas may be within a range from 0.03% to 15%.

A flow of the silicon containing gas may be within a range from 0.5 mL/min (sccm) to 10 mL/min (sccm).

A flow ratio of the oxygen containing gas to the entire process gas may be within a range from 5% to 99%.

A flow of the oxygen containing gas may be within a range from 50 mL/min (sccm) to 1000 mL/min (sccm).

The process gas may further include a nitrogen containing gas, and the formed silicon oxide film may be a silicon oxynitride film containing nitrogen.

A flow ratio of the nitrogen containing gas to the entire process gas may be within a range from 5% to 99%.

A flow of the nitrogen containing gas may be within a range from 60 mL/min (sccm) to 1000 mL/min (sccm).

The silicon containing gas may be SiCl₄, and a concentration of hydrogen atoms in the silicon oxide film measured by secondary ion mass spectrometry (SIMS) may be below to or equal to 9.9×10²⁰ atoms/cm³.

According to another aspect of the present invention, there is provided a silicon oxide film formed by using any of the above described methods.

According to another aspect of the present invention, there is provided a plasma CVD apparatus for forming a silicon oxide film on a target object by using a plasma CVD is method, the plasma CVD apparatus including: a processing container which accommodates the target object and has an opening on a top thereof; a dielectric member which closes the opening of the processing container; a planar antenna which provided to overlap on the dielectric member and has a plurality of holes for introducing microwaves into the processing container; a gas supply mechanism which supplies a process gas including a silicon containing gas and an oxygen containing gas into the processing container; an exhaust mechanism which depressurizes and exhausts an inside of the processing container; and a control unit which controls plasma CVD to set an inside pressure of the processing container within the range from 0.1 Pa to 6.7 Pa, to supply the process gas including the silicon containing gas and the oxygen containing gas from the gas supply mechanism into the processing container, to generate plasma by introducing microwaves through the planar antenna, and to form the silicon oxide film having an etching rate below or equal to 0.11 nm/s when a dilute hydrofluoric acid solution is used, on a target object.

### Advantageous Effects

According to a method for forming a silicon oxide film of the present invention, a high quality silicon oxide film (a silicon dioxide film or a silicon oxynitride film) having dense structure and high insulating properties can be formed by using a plasma CVD method.

Since a silicon oxide film obtained by the method of the present invention has dense structure and excellent insulating properties, and thus is high quality silicon oxide film, it can provide a highly reliable device. Accordingly, the method of the present invention has a high utility value in forming a silicon oxide film that is used as a gate insulation film or the like requiring high quality.

### BRIEF DESCRIPTION OF THE DRAWINGS

FIG. 1 is a schematic cross-sectional view showing an example of a plasma CVD apparatus suitable for forming a silicon oxide film by using a method according to the present invention;

FIG. 2 is a diagram showing a structure of a planar antenna in the apparatus of FIG. 1;

is FIG. 3 is a diagram for explaining a configuration of a control unit in the apparatus of FIG. 1;

FIGS. 4A and 4B are diagrams showing a process example of a method for forming a silicon oxide film, according to the present invention;

FIGS. 5A through 5D are graphs showing results of measuring gate leak currents (Jg) of MOS transistors having silicon dioxide films formed by using a method of the present invention and a conventional method;

FIG. 6 is a graph showing a relationship between a gate leak current (Jg) and an equivalent oxide film thickness (EOT);

FIGS. 7A through 7C are graphs showing results of SIMS measurement;

FIG. 8 is a graph showing a result of a wet etching test;

FIG. 9 is a graph showing a result of measuring concentrations of Si, N, and O in a silicon oxynitride film by using an XPS;

FIG. 10 is a graph showing a result of measuring a gate leak current of a MOS transistor having a silicon oxide film; and

FIG. 11 is a view for explaining a schematic configuration of a MOS type semiconductor memory device to which a method of the present invention is applicable.

### EXPLANATION ON REFERENCE NUMERALS

1: Processing Container
2: Holding Stage
3: Support Member
5: Heater
12: Exhaust Pipe
14, 15: Gas Introduction Unit
16: Transfer Hole
17: Gate Valve
18: Gas Supply Mechanism
19a: N-containing Gas Supply Source
19b: O-containing Gas Supply Source
19c: Si-containing Gas Supply Source
19d: Insert Gas Supply Source
19e: Cleaning Gas Supply Source
24: Exhauster
27: Microwave Introduction Mechanism
28: Penetration Plate
29: Seal Member
31: Planar Antenna
32: Microwave Radiation Hole
37: Waveguide
39: Microwave Generator
50: Control Unit
100: Plasma CVD Apparatus
101: Silicon Substrate
102a: Silicon Nitride Film Stacked Body
103: Gate Electrode
104: First Source and Drain
105: Second Source and Drain
111: First Insulation Film
112: Second Insulation Film
113: Third Insulation Film
114: Fourth Insulation Film
115: Fifth Insulation Film
201: MOS-type Semiconductor Memory Device

W: Semiconductor Wafer (Substrate)

### BEST MODE FOR CARRYING OUT THE INVENTION

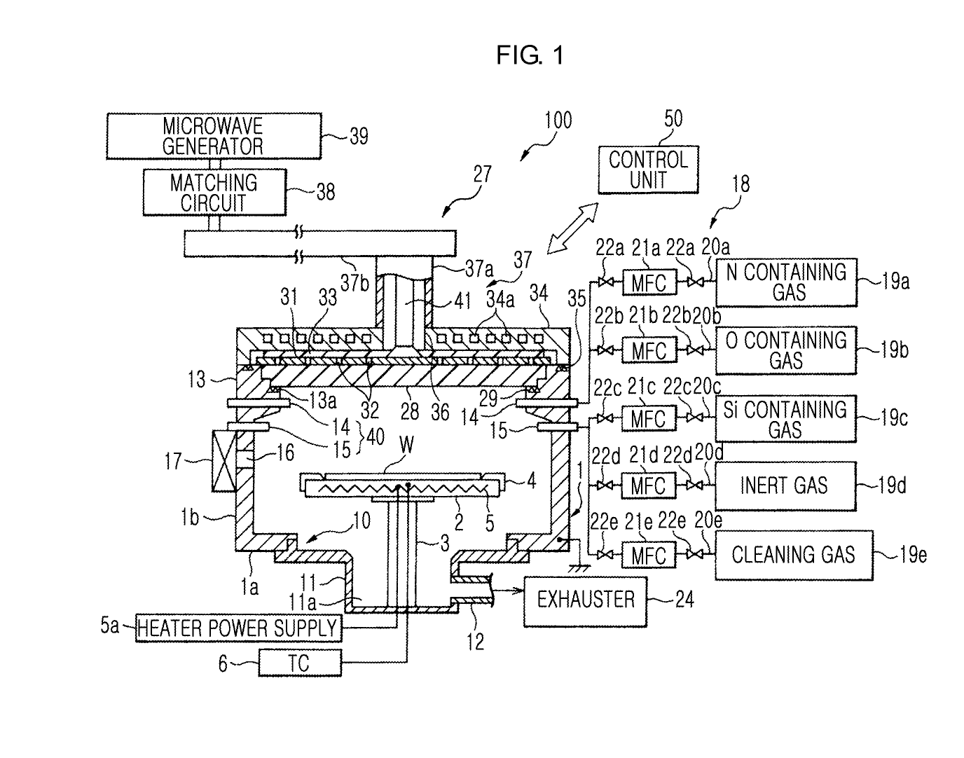

Hereinafter, the present invention will be described in detail by explaining exemplary embodiments of the invention with reference to the attached drawings. FIG. 1 is a schematic cross-sectional view showing a schematic configuration of plasma CVD apparatus 100 used for a method for forming a silicon oxide film of the present invention.

The plasma CVD apparatus 100 is an RLSA (Radial Line Slot Antenna) microwave plasma processing apparatus that can generate microwave excitation plasma having a high density and a low electron temperature, by introducing microwaves into a processing container through a planar antenna having a plurality of slots, specifically an RLSA and generating plasma. The plasma CVD apparatus 100 is able to perform a process using plasma having a low electron temperature from 0.7 eV to 2 eV, and a plasma density from 1×10¹⁰/cm³ to 5×10¹²/cm³. Accordingly, the plasma CVD apparatus 100 may be very suitably used to form a silicon oxide film by plasma CVD in manufacturing process of various kinds of semiconductors.

The plasma CVD apparatus 100 include, as main elements, an airtight processing container 1, a gas introduction unit connected to a gas supply mechanism 18 for supplying a gas into the processing container 1, an exhauster 24 constituting an exhaust mechanism for depressurizing and exhausting an inside of the processing container 1, a microwave introduction mechanism 27 disposed above the processing container 1 and introducing microwaves into the processing container 1, and a control unit 50 for controlling each element of the plasma CVD apparatus 100. Also, in the embodiment of FIG. 1, the gas supply mechanism 18 is integrally provided to the plasma CVD apparatus 100, but may not be integrally provided. The gas supply mechanism 18 may be provided outside the plasma CVD apparatus 100.

The processing container 1 is a grounded container having a substantially cylindrical shape. Alternatively, the processing container 1 may be a container having a prismatic shape. The processing container 1 has a bottom wall 1a and a side wall 1b that are formed of a material such as aluminum or the like.

A holding stage 2 for horizontally supporting a silicon wafer (hereinafter, simply referred to as a “wafer”) W constituting a target object is provided inside the processing container 1. The holding stage 2 is formed of a material having a high thermal conductivity, for example, a ceramic, such as AlN or the like. The holding stage 2 is held by a holding member 3 having a cylindrical shape and extending upward from a bottom center of an is exhaust chamber 11. The holding member 3 may be formed of a ceramic, such as AlN or the like.

A cover ring 4 for covering an outer edge portion of the holding stage 2 and guiding the wafer W is provided on the holding stage 2. The cover ring 4 is a ring-shaped member formed of a material such as quartz, AlN, Al₂O₃, SiN, or the like. The cover ring 4 may be configured to cover an entire surface of a holding stage, so as to prevent contamination.

A resistance heating type heater 5 as a temperature adjusting mechanism is embedded in the holding stage 2. The heater 5 heats the holding stage 2 by receiving power from a heater power supply 5a, and the wafer W constituting a substrate to be processed is uniformly heated by heat from the holding stage 2.

A thermocouple (TC) 6 is disposed at the holding stage 2. A temperature is measured by using the thermocouple 6, and thus a heating temperature of the wafer W is controllable, for example, in the range from room temperature to 900° C.

Also, the holding stage 2 includes wafer holding pins (not shown) for holding and elevating the wafer W. Each wafer holding pin is provided to be able to protrude and retract with respect to a surface of the holding stage 2.

A circular opening 10 is formed substantially at a center of the bottom wall 1a of the processing container 1. An exhaust chamber 11 is continuously provided on the bottom wall 1a. The exhaust chamber 11 communicates with the opening 10 and protrudes downward from the bottom wall 1a. The exhaust chamber 11 is connected to an exhaust pipe 12, and is connected to the exhauster 24 through the exhaust pipe 12.

A plate 13 is disposed on an upper end of the side wall 1b forming the processing container 1. The plate 13 is formed of a metal and operates as a lid for opening and closing the processing container 1. A bottom inner circumference of the plate 13 protrudes inward (toward a space inside the processing container 1) to form a ring-shaped holder 13a.

A gas introduction unit 40 is provided at the plate 13. The gas introduction unit 40 includes a first gas introduction unit 14 having a ring shape and a first gas introduction hole, and a second gas introduction unit 15 having a ring shape and a second gas introduction hole. In other words, the first and second gas introduction units 14 and 15 are provided in 2 stages, top stage and bottom stage. Each of the gas introduction units 14 and 15 is connected to the gas supply mechanism 18 for supplying a process gas or a plasma excitation gas. Alternatively, the first and second gas introduction units 14 and 15 may each have a nozzle shape or a shower head shape. Alternatively, the first and second gas introduction units 14 and 15 may be provided as a single shower head.

The side wall 1b of the processing container 1 includes a transfer hole 16 for transferring the wafer W between the plasma CVD apparatus 100 and a transfer chamber (not shown) adjacent to the plasma CVD apparatus 100, and a gate valve 17 for opening and closing the transfer hole 16.

The gas supply mechanism 18 includes, for example, a nitrogen containing gas (N-containing gas) supply source 19a, an oxygen containing gas (O-containing gas) supply source 19b, a silicon containing gas (Si-containing gas) supply source 19c, an inert gas supply source 19d, and a cleaning gas supply source 19e. The N-containing gas supply source 19a and the O-containing gas supply source 19b are connected to the first gas introduction unit 14 as a top stage of the two stages. Also, the Si-containing gas supply source 19c, the inert gas supply source 19d, and the cleaning gas supply source 19e are connected to the second gas introduction unit 15 as a bottom stage of the two stages. The cleaning gas supply source 19e is used to clean unnecessary films attached inside the processing container 1. Also, the gas supply mechanism 18 may include, for example, a purge gas supply source or the like used to replace an atmosphere inside the processing container 1, as another gas supply source (not shown).

For example, N₂, NH₃, NO, or the like may be used as the nitrogen containing gas.

In the present invention, tetrachlorosilane (SiCl₄) or hexachlorosilane (Si₂Cl₆), silane (SiH₄), disilane (Si₂H₆), or the like may be used as the silicon containing gas. Here, since compounds SiCl₄ and Si₂Cl₆ formed of silicon atoms and chlorine atoms do not contain hydrogen in molecules, SiCl₄ and Si₂Cl₆ may be preferably used in the present invention.

Also, for example, O₂, NO, N₂O, or the like may be used as the oxygen containing gas.

Also, for example, a noble gas may be used as the inert gas. The noble gas helps generation of stable plasma, as a plasma excitation gas, and may include, for example, an is Ar gas, a Kr gas, an Xe gas, an He gas, or the like. The noble gas may be also used as a carrier gas for supplying the silicon containing gas, such as SiCl₄.

The nitrogen containing gas or the oxygen containing gas reaches the first gas introduction unit 14 from the N-containing gas supply source 19a or the O-containing gas supply source 19b of the gas supply mechanism 18, respectively, through a gas line 20a or 20b, and is introduced into the processing container 1 from a gas introduction hole (not shown) of the first gas introduction unit 14. Meanwhile, the silicon containing gas, the inert gas, and the cleaning gas reach the second gas introduction unit 15 respectively from the Si-containing gas supply source 19c, the inert gas supply source 19d, and the cleaning gas supply source 19e respectively through gas lines 20c through 20e, and are introduced into the processing container 1 from a gas introduction hole (not shown) of the second gas introduction unit 15. Mass flow controllers 21a through 21e and opening and closing valves 22a through 22e provided respectively at front and behind the mass flow controllers 21a through 21e are respectively provided in the gas lines 20a through 20e respectively connected to the gas supply sources. Change of supplied gas, a flow of supplied gas, etc. are controllable by such a configuration of the gas supply mechanism 18. Here, the noble gas for plasma excitation, such as Ar or the like, is a predetermined gas. The noble gas does not necessarily have to be supplied at the same time as supply of the process gas, but it is preferable that the noble gas is supplied in order to stabilize plasma. An amount of the noble gas is preferably smaller than an amount of the nitrogen containing gas.

The exhauster 24 constituting as an exhaust mechanism includes a high speed vacuum pump, such as a turbomolecular pump or the like. As described above, the exhauster 24 is connected to the exhaust chamber 11 of the processing container 1 through the exhaust pipe 12. By operating the exhauster 24, a gas inside the processing container 1 uniformly flows toward a space 11a of the exhaust chamber 11, and is also externally exhausted from the space 11a through the exhaust pipe 12. Accordingly, it is possible to depressurize the inside of the processing container 1, for example, up to 0.133 Pa, at a high speed.

A configuration of the microwave introduction mechanism 27 will now be described. The microwave introduction mechanism 27 include, as main elements, a penetration plate is 28, a planar antenna 31, a wavelength-shortening material 33, a cover member 34, a waveguide 37, and a microwave generator 39.

The penetration plate 28 through which microwaves penetrate is arranged on the holder 13a protruding toward an inner circumference of the plate 13. The penetration plate 28 is formed of a dielectric material, for example, a ceramic such as quartz, Al₂O₃, AlN, or the like. A space between the penetration plate 28 and the holder 13a is sealed air tight by disposing a seal member 29. Accordingly, the processing container 1 is held air tight.

The planar antenna 31 is provided above the penetration plate 28 and faces the holding stage 2. The planar antenna 31 has a disk shape. However, a shape of the planar antenna 31 is not limited to the disk shape, and the planar antenna 31 may have a rectangular plate shape. The planar antenna 31 is fastened to a top end of the plate 13.

The planar antenna 31 is formed of, for example, a copper plate, a nickel plate, an SUS plate, or an aluminum plate, wherein the plate used to form the planar antenna 31 has surfaces coated with gold or silver. The planar antenna 31 includes a plurality of microwave radiation holes 32 each having a slot shape and radiating microwaves. The microwave radiation holes 32 have a predetermined pattern and are formed by penetrating through the planar antenna 31.

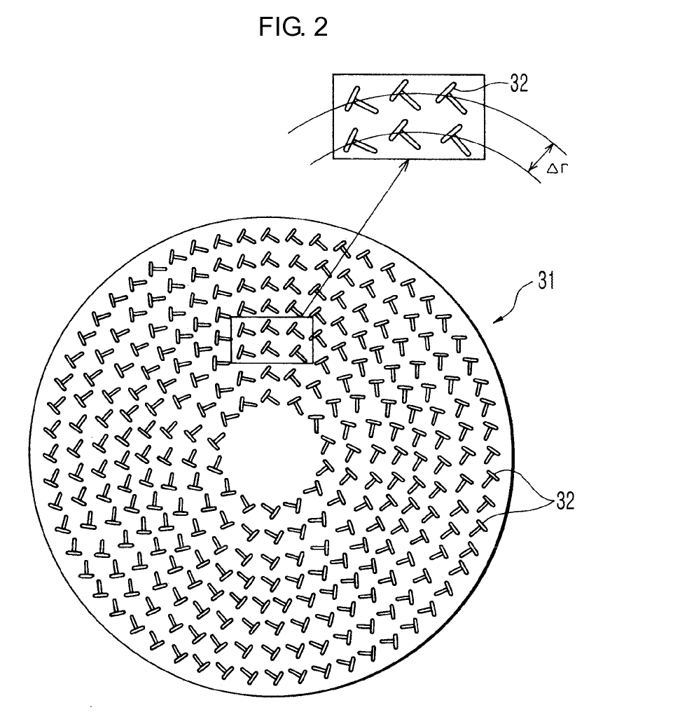

Each microwave radiation hole 32 has, for example, a narrow and long rectangular shape (slot shape) as shown in FIG. 2, and two adjacent microwave radiation holes form a pair. The adjacent microwave radiation holes 32 are typically disposed in a “T”, “L”, or “V” shape. The microwave radiation holes 32 are disposed in combination shape of such predetermined shapes, and overall, are also arranged in a concentric shape.

Lengths or arranged intervals of the microwave radiation holes 32 are determined according to a wavelength (λg) of microwaves. For example, an interval of the microwave radiation holes 32 is from

$$\frac{λ g}{4}$$

to λg. In FIG. 2, an interval between the adjacent microwave radiation holes 32 arranged in a concentric shape is denoted by Δr. Alternatively, a shape of each microwave radiation hole 32 may vary and be, for example, a circular shape, an arc shape, or the like. Also, an arrangement shape of the microwave radiation holes 32 is not specifically limited, and may be, for example, a spiral shape or a radial shape, aside from the concentric shape.

The wavelength-shortening material 33, having a dielectric constant higher than that of vacuum, is provided on a top surface of the planar antenna 31. The wavelength-shortening material 33 shortens a wavelength of microwaves in order to adjust plasma, since the wavelength of the microwaves becomes longer in a vacuum.

Also, the planar antenna 31 and the penetration plate 28, and the wavelength-shortening material 33 and the planar antenna 31 may contact or be separated from each other, but preferably contact each other.

The cover member 34, which is conductive, may be formed on the processing container 1 so as to cover the planar antenna 31 and the wavelength-shortening material 33. The cover member 34 may be formed of, for example, a metal material such as aluminum, stainless steel, or the like. A top of the plate 13 and the cover member 34 are sealed by a seal member 35. A cooling water path 34a may be formed inside the cover member 34. Cooling water flows through the cooling water path 34a, thereby cooling the cover member 34, the wavelength-shortening material 33, the planar antenna 31, and the penetration plate 28. Also, the cover member 34 is grounded.

An opening 36 is formed on a center of a top wall (ceiling portion) of the cover member 34, and is connected to one end of the waveguide 37. Other end of the waveguide 37 is connected to the microwave generator 39 for generating microwaves, through a matching circuit 38.

The waveguide 37 includes a coaxial waveguide 37a having a circular cross-section and extending upward from the opening 36 of the cover member 34, and a rectangular waveguide 37b connected to an upper end of the coaxial waveguide 37a and extending in a horizontal direction.

An inner conductor 41 extends at a center of the coaxial waveguide 37a. A bottom portion of the inner conductor 41 is connected and fixed to a center of the planar antenna 31. According to such a configuration, microwaves are efficiently uniformly propagated in a radial shape to the planar antenna 31 through the inner conductor 41 of the coaxial waveguide 37a.

By using the microwave introduction mechanism 27 having the above configuration, is microwaves generated in the microwave generator 39 are propagated to the planar antenna 31 through the waveguide 37, and then are introduced into the processing container 1 through the penetration plate 28. Also, a frequency of the microwaves may be preferably, for example, 2.45 GHz, and may be 8.35 GHz, 1.98 GHz, or the like, aside from 2.45 GHz.

Each element of the plasma CVD apparatus 100 is connected to and controlled by the control unit 50. The control unit 50 includes a computer, and, for example, includes a process controller 51 having a CPU, and a user interface 52 and a storage unit 53 connected to the process controller 51, as shown in FIG. 3. The process controller 51 is a control means that generally controls elements of the plasma CVD apparatus 100 that are related to, for example, process conditions, such as a temperature, a pressure, a gas flow, a microwave output, etc. (for example, the heater power supply 5a, the gas supply mechanism 18, the exhauster 24, the microwave generator 39, etc.).

The user interface 52 includes a keyboard for a process manager to perform input manipulation or the like of a command in order to manage the plasma CVD apparatus 100, a display for visually displaying an operation situation of the plasma CVD apparatus 100, and the like. Also, the storage unit 53 stores a control program (software) for executing various processes in the plasma CVD apparatus 100 under a control of the process controller 51, or stores a recipe on which process condition data, etc. is recorded.

Also, if required, a predetermined recipe is called from the storage unit 53 by instructions from the user interface 52 or the like and executed in the process controller 51, thereby performing a desired process in the processing container 1 of the plasma CVD apparatus 100 under a control of the process controller 51. The control program and, the recipe such as process condition data may be stored in a computer readable recording medium, such as a CD-ROM, a hard disk, a flexible disk, a flash memory, a DVD, a Blu-ray disk, or the like, and accessed therefrom. Alternatively, the control program and the recipe such as the process condition data may be frequently received from another device, for example, through an exclusive line, and accessed online.

Next, a deposition process of a silicon oxide film by a plasma CVD method using the RLSA type plasma CVD apparatus 100 will be described. First, the gate valve 17 is opened and the wafer W is transferred into the processing container 1 through the transfer is hole 16 and placed on the holding stage 2. Then, while depressurizing and exhausting the inside of the processing container 1, the silicon containing gas and the oxygen containing gas, and if required, the nitrogen containing gas and the inert gas, are introduced into the processing container 1 respectively from the N-containing gas supply source 19a, the O-containing gas supply source 19b, the Si-containing gas supply source 19c, and the inert gas supply source 19d of the gas supply mechanism 18 respectively through the gas introduction units 14 and 15, with predetermined flow. Also, the inside of the processing container 1 is set to a predetermined pressure. Conditions at this time will be described later.

Then, microwaves of a predetermined frequency, for example, 2.45 GHz, generated in the microwave generator 39 are introduced to the waveguide 37 through the matching circuit 38. The microwaves introduced to the waveguide 37 sequentially pass through the rectangular waveguide 37b and the coaxial waveguide 37a, and are supplied to the planar antenna 31 through the inner conductor 41. The microwaves are propagated in a radial shape from the coaxial waveguide 37a toward the planar antenna 31. Also, the microwaves are radiated to a space above the wafer W in the processing container 1 from the microwave radiation holes 32, each having a slot shape, of the planar antenna 31 through the penetration plate 28.

An electric field is formed inside the processing container 1 by the microwaves radiated to the processing container 1 from the planar antenna 31 through the penetration plate 28, and thus the silicon containing gas and the oxygen containing gas, and if additionally required, the nitrogen containing gas and the inert gas, are each plasmatized. Then, a material gas is efficiently dissociated in the plasma, and a thin film of silicon dioxide (SiO₂) or silicon oxynitride (SiON) is deposited by a reaction of active species of SiCl₃, SiCl₂, SiCl, Si, O, N, etc.

The above conditions are stored as a recipe in the storage unit 53 of the control unit 50. Also, the process controller 51 reads the recipe, and transmits a control signal to each element of the plasma CVD apparatus 100, for example, the heater power supply 5a, the gas supply mechanism 18, the exhauster 24, the microwave generator 39, etc., thereby realizing a plasma CVD process performed under a desired condition.

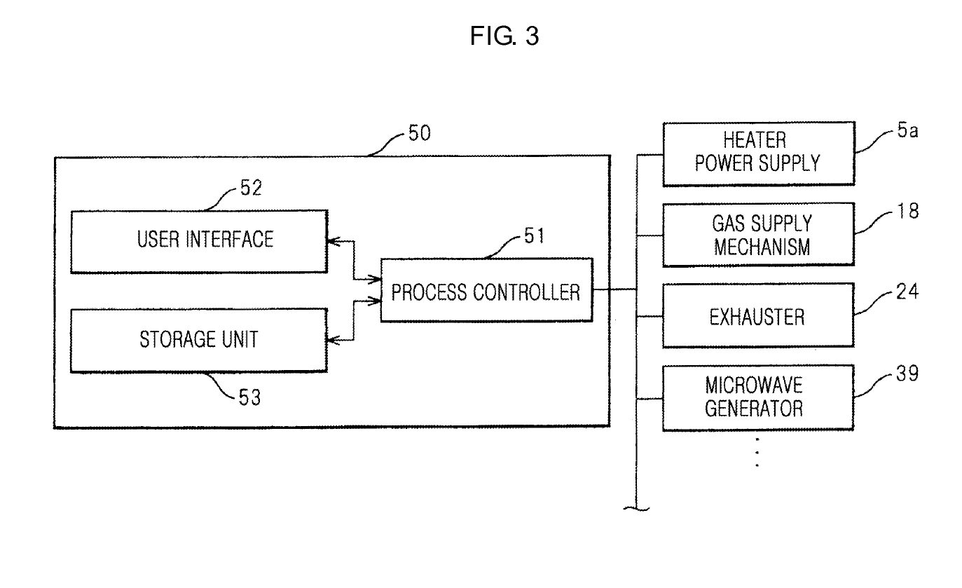

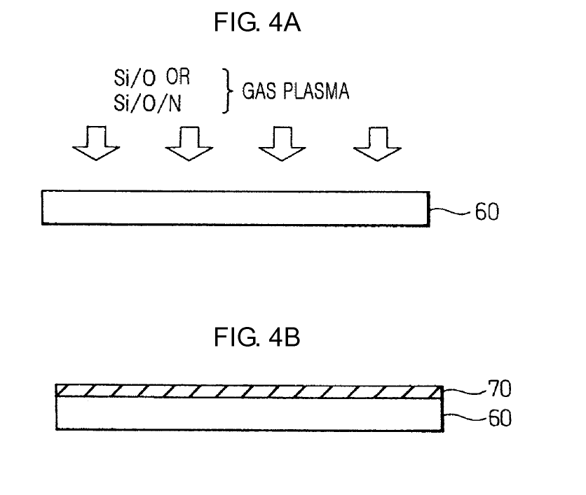

FIGS. 4A and 4B are process diagrams showing processes of forming a silicon oxide film performed by the plasma CVD apparatus 100. As shown in FIG. 4A, a plasma CVD process is performed on a predetermined base layer (for example, a Si substrate) 60 by using the plasma CVD apparatus 100. The plasma CVD process is performed under following conditions by using a film-forming gas including the silicon containing gas and the oxygen containing gas, and if required, the nitrogen containing gas.

A process pressure may be set within the range from 0.1 Pa to 6.7 Pa, and preferably within the range from 0.1 Pa to 4 Pa. The lower the process pressure the better, and the lowest limit 0.1 Pa of the range is set based on a restriction of an apparatus (limitation of a high vacuum level). When the process pressure exceeds 6.7 Pa, a SiCl₄ gas does not be dissociated, and thus a film may not be sufficiently formed.

Also, a ratio of a flow of the silicon containing gas to a flow of all gases (for example, a percentage of (flow of SiCl₄ gas/flow of all gases)) is preferably from 0.03% to 15%, and more preferably from 0.03% to 1%. Also, the flow of the silicon containing gas may be set to be preferably from 0.5 mL/min (sccm) to 10 mL/min (sccm), and more preferably from 0.5 mL/min (sccm) to 2 mL/min (sccm).

Also, a ratio of a flow of the oxygen containing gas to the flow of the all gases (for example, a percentage of (flow of O₂ gas/flow of all gases)) is preferably from 5% to 99%, and more preferably from 40% to 99%. The flow of the oxygen containing gas is set to be preferably from 50 mL/min (sccm) to 1000 mL/min (sccm), and more preferably from 50 mL/min (sccm) to 600 mL/min (sccm).

Also, a ratio of a flow of the inert gas to the flow of the all gases (for example, a percentage of (flow of Ar gas/flow of all gases)) is preferably from 0% to 90%, and more preferably from 0% to 60%. The flow of the inert gas is set to be preferably from 0 mL/min (sccm) to 1000 mL/min (sccm), and more preferably from 0 mL/min (sccm) to 200 mL/min (sccm).

Also, when a silicon oxynitride film (SiON film) is formed, a ratio of a flow of the nitrogen containing gas to the flow of the all gases (for example, a percentage of (flow of N₂ gas/flow of all gases)) is preferably from 5% to 99%, and more preferably from 40% to 99%. The flow of the nitrogen containing gas is set to be preferably from 60 mL/min (sccm) to 1000 mL/min (sccm), and more preferably from 100 mL/min (sccm) to 600 mL/min (sccm).

Also, a process temperature of the plasma CVD process may be set to be such that a temperature of the holding stage 2 is from 300° C. to 600° C., and preferably from 400° C. to 600° C.

Also, it is preferable that a microwave output in the plasma CVD apparatus 100 is within the range from 0.25 W/cm² to 2.56 W/cm² as power density per area of the penetration plate 28. The microwave output may be selected from a range, for example, from 500 W to 5000 W to be a power density within the above range according to a purpose.

Si/O or Si/N plasma is formed via plasma CVD, and as shown in FIG. 4B, a silicon oxide film (an SiO₂ film or an SiON film) 70 may be deposited. It is advantageous since the plasma CVD apparatus 100 may form a silicon oxide film 70 having a film thickness within a range, for example, from 2 nm to 300 nm, preferably from 2 nm to 50 nm.

The silicon oxide film 70 obtained as described above is a high quality insulation film having excellent insulating properties, and may increase reliability of a device. Accordingly, the silicon oxide film 70 formed according to the method of the present invention may preferably be used for a purpose that requires high reliability, for example, for a gate insulation film (tunnel insulation film), an interlayer insulation film, a liner around a gate, etc. of a transistor or a semiconductor memory device.

Next, conditions very suitable for the plasma CVD process will be described using experiment data as an example, on which the present invention is based.

(1) Forming of Silicon Dioxide Film (SiO₂ Film):

Here, in the plasma CVD apparatus 100, an SiO₂ film having a film thickness of 7 nm is formed on a silicon substrate by using an SiCl₄ gas or an Si₂H₆ gas, and an O₂ gas as process gases under following conditions. Also, after forming the SiO₂ film on a plurality of substrates, unnecessary deposited SiO₂ films in the chamber is removed by supplying a ClF₃ gas as a cleaning gas and heating the gas from 100° C. to 500° C., preferably from 200° C. to 300° C. Alternatively, when an NF₃ gas is used as a cleaning gas, plasma is generated at a temperature from room temperature to 300° C. and the unnecessary deposited SiO₂ films are removed. When a film is repeatedly formed and thickly deposited, the film is peeled off due to stress, and thus particles are generated. The substrate is contaminated by the particles, and thus the chamber needs to be cleaned to prevent the contamination.

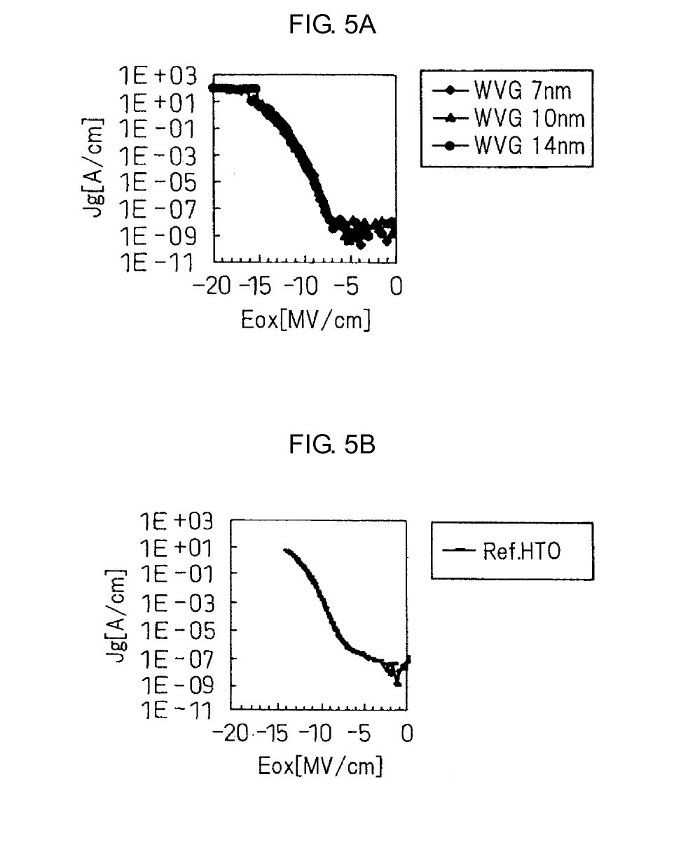

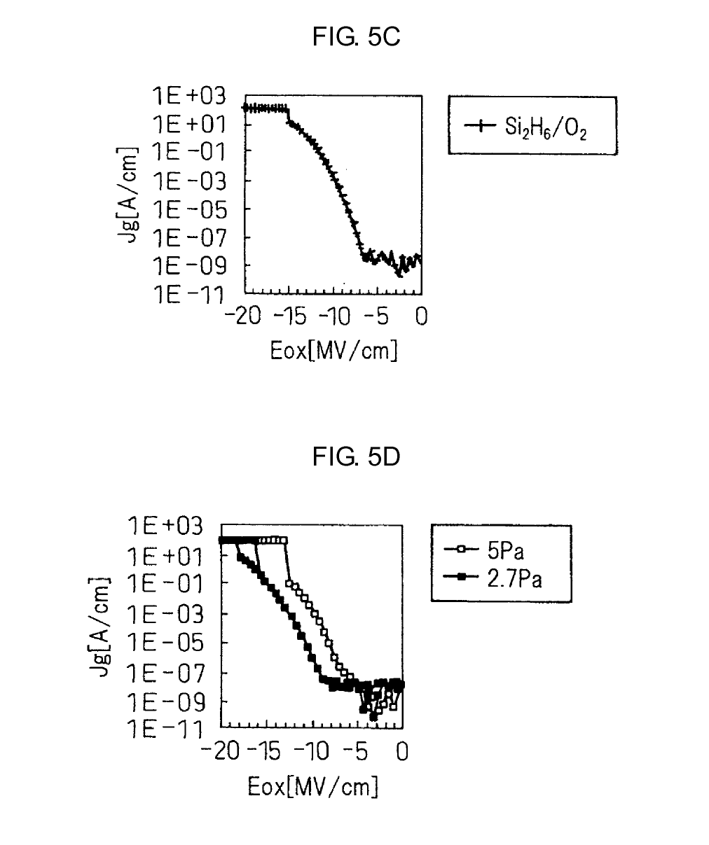

A transistor having a MOS structure was manufactured by forming a polysilicon layer having a film thickness of 150 nm on the formed SiO₂ film, and forming a polysilicon electrode by using a pattern formed by a photolithography technology. A gate leak current (Jg) of the transistor having the MOS structure using such an SiO₂ film as a gate insulation film was measured according to a common method. Also, for comparison, gate leak currents of transistors using, as gate insulation films, silicon oxide films formed via thermal CVD (HTO: High Temperature Oxide) and thermal oxidation (WVG: method of generating and supplying vapor by combusting O₂ and H₂ by using a vapor generator) according to following conditions were also measured. Results of measuring the gate leak currents (I-V curves) are shown in FIGS. 5A through 5D. FIG. 5A shows the result of thermal oxidation, FIG. 5B shows the result of thermal CVD (HTO), FIG. 5C shows the result of Si₂H₆+O₂ (the method of the present invention), and FIG. 5D shows the result of SiCl₄+O₂ (the method of the present invention).

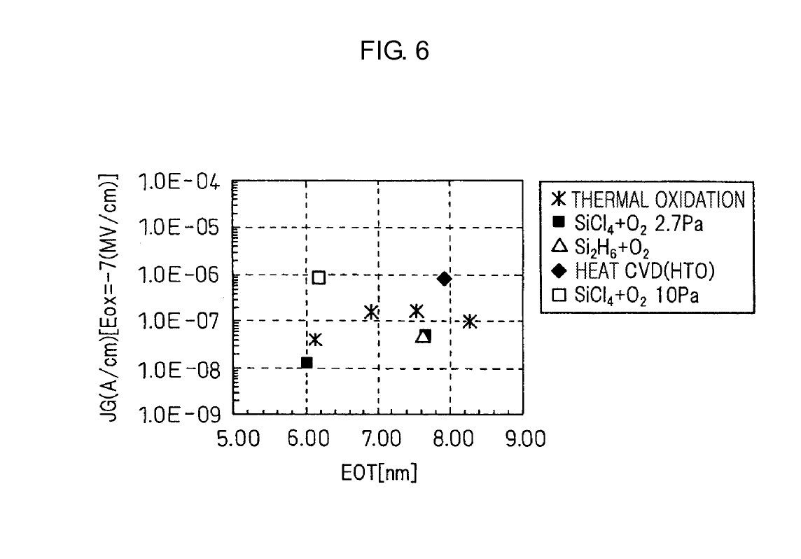

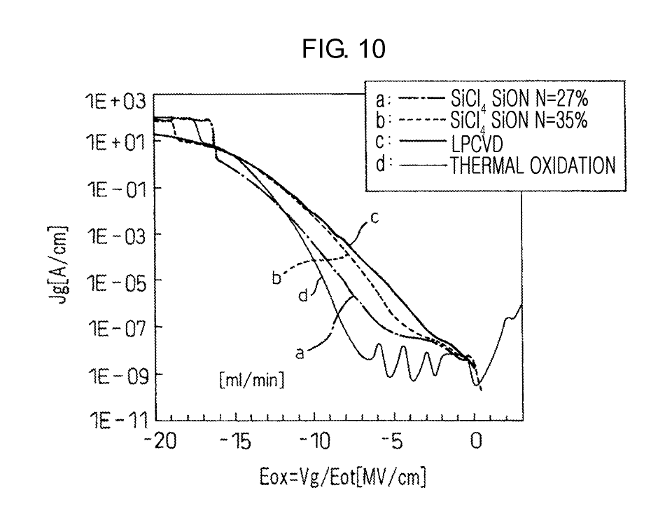

Also, a graph plotted with a relationship between an equivalent oxide thickness (EOT) and a gate leak current (Jg) of each silicon oxide film is shown in FIG. 6. Eox (=applied voltage/oxide film pressure) of FIG. 10 is defined by Eox=Vg/Eot (MV/cm), in which a gate voltage (Vg) is used.

(Plasma CVD Conditions)

Process Temperature (Holding Stage): 400° C.

Microwave Power: 3 kW (Power Density 1.53 W/cm², per Penetration Plate Area)

Process Pressure: 2.7 Pa, 5 Pa, or 10 Pa

SiCl₄ Flow (or Si₂H₆Flow): 1 mL/min (sccm)

O₂ Gas Flow: 400 mL/min (sccm)

Ar Gas Flow: 40 mL/min (sccm)

(Thermal CVD (HTO) Conditions)

Process Temperature: 780° C.

Process Pressure: 133 Pa

SiH₂Cl₂ Gas+N₂O Gas: 100+1000 mL/min (sccm)

(Thermal Oxidation Condition: WVG)

Process Temperature: 950° C.

Process Pressure: 40 kPa

Vapor: O₂/H₂Flow=900/450 mL/min (sccm)

Also, in FIGS. 5 and 6, an SiO₂ film was formed by using the method of the present invention, in which plasma CVD was performed at a process pressure of 2.7 Pa (and 5 Pa) by using SiCl₄ or Si₂H₆, and had a low gate leak current, and thus had excellent electric characteristics as an insulation film. In other words, the SiO₂ film formed by the method of the present invention had insulating properties comparable with those of an SiO₂ film formed by using a thermal CVD method (HTO) or a thermal oxidation method in which film formation is performed at a high temperature. According to above results, it was determined that the SiO₂ film formed by the method of the present invention has excellent insulating properties and reliability.

Also, from FIGS. 5 and 6, it was determined that a gate leak current of the silicon oxide film formed by using the plasma CVD apparatus 100 is reduced as a process pressure during the film-formation is decreased. Accordingly, in order to improve electric characteristics (gate leak current suppression) of a silicon oxide film, it was determined that a process pressure during the plasma CVD may be more preferably set in the range from 0.1 Pa to 4 Pa.

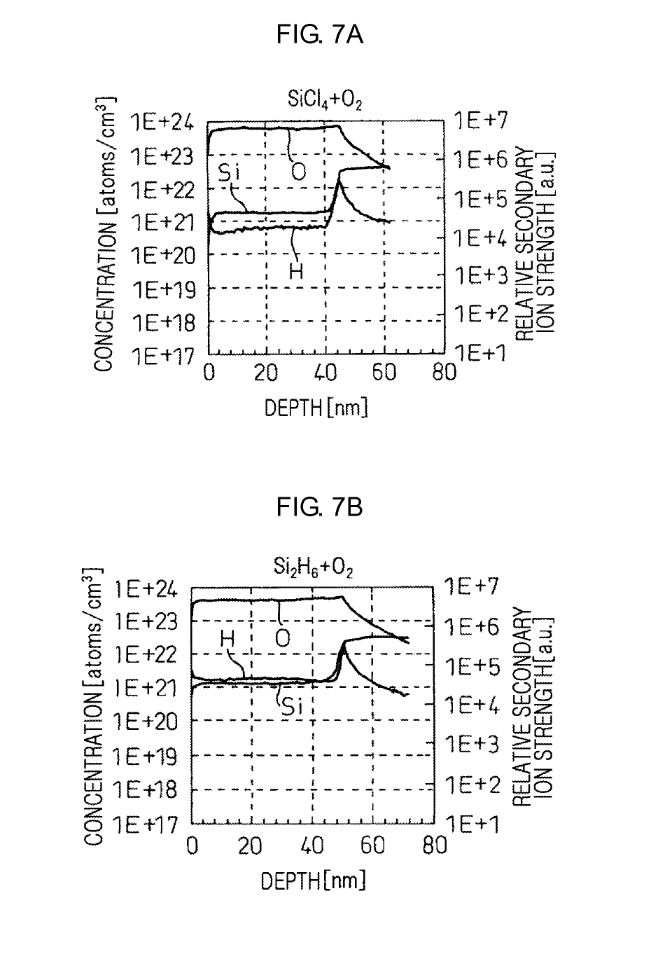

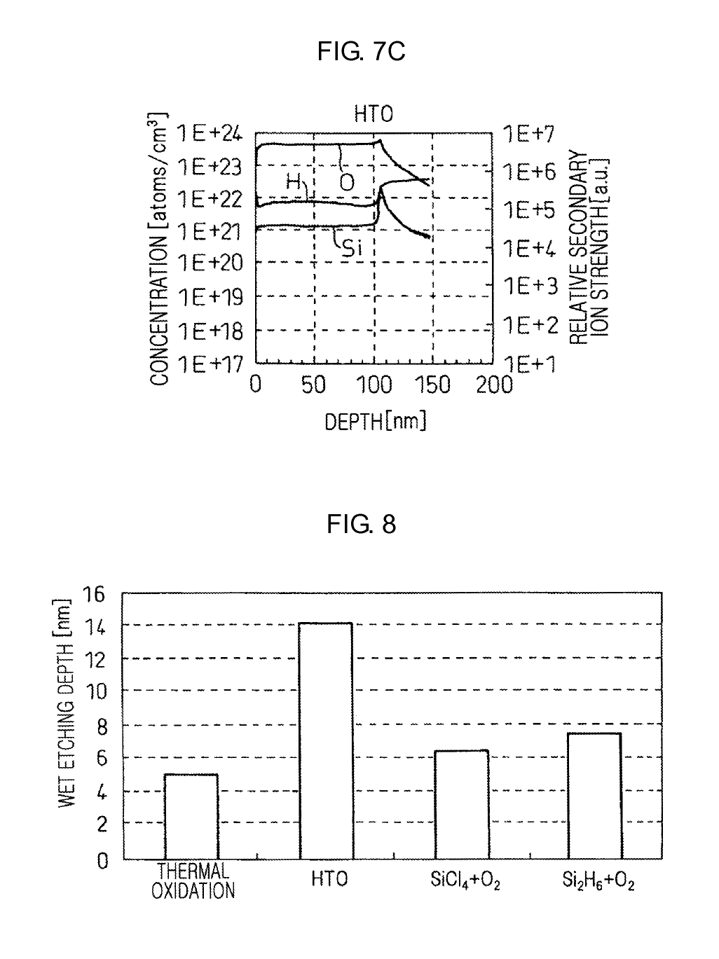

Then, a concentration of each of hydrogen, oxygen, and silicon atoms included in the SiO₂ film was measured by using secondary ion mass spectrometry (SIMS), with respect to each SiO₂ film formed of SiCl₄+O₂ (the method of the present invention), formed of Si₂H₆+O₂ (the method of the present invention), and formed by using thermal CVD (HTO). Results thereof are shown in FIG. 7. Also, the SIMS measurements were performed under following conditions.

Used Apparatus: ATOMIKA 4500 type (manufactured by ATOMIKA) Secondary Ion Mass Spectrometry Apparatus

First Ion Condition: Cs⁺, 1 keV, and about 20 nA

Examined Region: about 350×490 μm

Analyzed Region: about 65×92 μm

Secondary Ion Polarity: Negative Electrification Compensation: Present

Also, a hydrogen atom weight in the SIMS result is obtained by converting secondary ionic strength of H to an atom concentration by using a relative sensitivity factor (RSF) calculated by using an H concentration (6.6×10²¹ atoms/cm³) of a standard sample measured by RBS/HR-ERDA (High Resolution Elastic Recoil Detection Analysis) (RBS-SIMS Measuring Method).

FIG. 7A shows a result of SiCl₄+O₂ (the method of the present invention), FIG. 7B shows a result of Si₂H₆+O₂ (the method of the present invention), and FIG. 7C shows a result of thermal CVD (HTO). It is determined from FIGS. 7A through 7C, that a concentration of hydrogen atoms included in the SiO₂ film formed by the method of the present invention is significantly small compared to that included in the SiO₂ film formed by the thermal CVD (HTO). Specifically, the concentration of hydrogen atoms included in the SiO₂ film formed by using SiCl₄ and O₂, which do not include hydrogen, as film-forming materials was 4×10²⁰ atoms/cm³, which was a detection limit level of a SIMS-RBS measuring device. Also, when Si₂H₆ and O₂ were used as film-forming materials, the concentration of hydrogen atoms was 1.5×10²¹ atoms/cm³. Based on the above results, it was determined that the SiO₂ film obtained by the method of the present invention includes a low amount of hydrogen in the film, unlike an SiO₂ film obtained by thermal CVD (HTO) of a conventional method.

Next, each SiO₂ film formed under the above conditions was processed with 0.5 wt % dilute hydrofluoric acid (HF) for 60 seconds to measure an etching depth, thereby evaluating etching tolerance. Results thereof are shown in FIG. 8. An etching rate of an SiO₂ film obtained by using SiCl₄+O₂ as a film-forming material according to the method of the present invention was 0.107 nm/s, and an etching rate of an SiO₂ film obtained by using Si₂H₆+O₂ as a film-forming material was 0.11 nm/s. Meanwhile, an etching rate of an SiO₂ film formed by thermal CVD (HTO) at 780° C. was 0.23 nm/s, and an etching rate of an SiO₂ film formed by thermal oxidation at 950° C. was 0.087 nm/s. From these results, although the SiO₂ film obtained by the method of the present invention using SiCl₄+O₂ or Si₂H₆+O₂ as a film-forming raw material was formed at 400° C., the etching rate with respect to the 0.5% dilute hydrofluoric acid solution was low, i.e., below or equal to 0.11 nm/s, and thus was a highly dense film having an etching tolerance at the same level as that of a thermal oxidation film formed at 950° C. Accordingly, in the method of the present invention, increase of a thermal budget may be remarkably suppressed compared to a conventional film-forming method, while a dense, high quality SiO₂ film may be formed.

(2) Forming of Silicon Oxynitride Film (SiON Film):

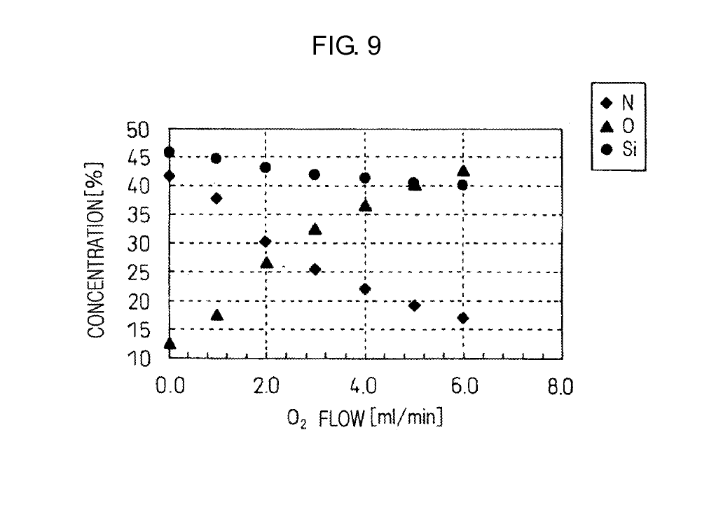

Here, the plasma CVD apparatus 100 formed a silicon oxynitride film (SiON film) having a film thickness of 14 nm on a silicon substrate under following conditions, by using an SiCl₄ gas, an N₂ gas, and an O₂ gas as process gases. When 24 hours has passed after the SiON film was formed, a concentration of each of Si, O, and N in the SiON film was measured via X-ray photoelectron spectroscopy (XPS) analysis. Results of XPS analysis are shown in FIG. 9.

Also, a transistor having a MOS structure was manufactured by forming a polysilicon layer having a film thickness of 150 nm on the formed SiON film, and forming a polysilicon electrode by forming a pattern by using a photolithography technology. As such, a gate leak current of the transistor having the MOS structure in which the SiON film as a gate insulation film is used, was measured according to a common method. Also, for comparison, a gate leak current of a transistor using a silicon dioxide film formed by LPCVD and thermal oxidation (WVG: using a vapor generator) according to the following conditions, as a gate insulation film, was measured. Results of measuring the gate leak currents (1-V curves) are shown in FIG. 10.

(Plasma CVD Conditions)

Process Temperature (Holding Stage): 400° C.

Microwave Power: 3 kW (Power Density 1.53 W/cm²; per Penetration Plate Area)

Process Pressure: 2.7 Pa

SiCl₄ Flow: 1 mL/min (sccm)

N₂ Gas Flow: 450 mL/min (sccm)

O₂ Gas Flow: 0 (not added), 1, 2, 3, 4, 5, and 6 mL/min (sccm).

Ar Gas Flow Rate: 40 mL/min (sccm)

(LPCVD Conditions)

Process Temperature: 780° C.

Process Pressure: 133 Pa

SiH₂Cl₂ Gas+NH₃ Gas: 100+1000 mL/min (sccm)

(Thermal Oxidation Conditions: WVG)

Process Temperature: 950° C.

Process Pressure: 40 kPa

Vapor:

$$\frac{{O}_{2}}{{H}_{2}} Flow = \frac{900}{450} mL \text{/} min ( sccm )$$

FIG. 9 is a graph showing, as results of measuring the concentration of each of Si atoms, O atoms, and N atoms in the SiON film via XPS analysis, the correlation between an O₂ flow during plasma CVD in a horizontal axis and the concentration of the above atoms. In FIG. 9, it was determined that when the O₂ flow during the plasma CVD is increased, the N concentration decreased in inverse proportion.

Also, the concentration of hydrogen atoms of the obtained SiON film measured by secondary ion mass spectrometry (SIMS) was below or equal to 9.9×10²⁰ atoms/cm³. Also, it was determined that an N—H bond does not exist in the SiON film, since a peak of the N—H bond was not detected in a measurement by Fourier transform infrared spectroscopy (FT-IR).

Also, from FIG. 10, it was shown that the SiON film (refer to curves a and b) formed by the method of the present invention had a high gate leak current (Jg) compared to the SiO₂ film (refer to a curve c) formed by LPCVD (refer to the curve c) or thermal oxidation in a low electric field side, but had a low gate leak current in a high electric field side since the SiON film is difficult to break down compared to the SiO₂ film formed by LPCVD or thermal oxidation in a high electric field side. From these results, it was determined that the SiON film formed by using the method of the present invention was a high quality SiON film that is identical to the SiO₂ film formed by using the LPCVD method or thermal oxidation method in terms of insulating properties and reliability (durability).

Also, it was determined from the curves a through c of FIG. 10, that as the concentration of nitrogen in the SiON film decreased, the gate leak current reduced. Accordingly, in order to improve electric characteristics of the SiON film (suppress the gate leak current), it was determined that a ratio of the flow of the oxygen containing gas to the flow of the all gases (for example, a percentage of flow rate of O₂ gas/flow rate of all gales) is preferably from 0.1% to 20%, more preferably from 0.1% to 3%, in the plasma CVD.

As such, in the method for forming the silicon oxide film of the present invention, the plasma CVD was performed by selecting a flow ratio of a film-forming gas including an Si-containing gas (an SiCl₄ gas or an Si₂H₆ gas) and an oxygen containing gas, and a process pressure, thereby forming a dense, high quality silicon oxide film having excellent insulating properties on the wafer (W). The silicon oxide film formed as such can be advantageously used as a gate insulation film of, for example, a MOS-type semiconductor memory device.

Also, in the method for forming the silicon oxide film of the present invention, the silicon oxide film that does not contain H atoms originated from a material can be formed by using, specifically, SiCl₄ or Si₂Cl₆ as a film-forming material. It is thought that the SiCl₄ gas used in the present invention is dissociated according to following steps from i) to iv) in plasma.

i) SiCl₄→SiCl₃+Cl

ii) SiCl₃→SiCl₂+Cl+Cl

iii) SiCl₂→SiCl+Cl+Cl+Cl

iv) SiCl→Si+Cl+Cl+Cl+Cl

(Here, Cl denotes ions)

In plasma having a high electron temperature, such as plasma used in a conventional plasma CVD method, the dissociation reaction shown in the i) to iv) may easily occur due to high energy of the plasma, and thus SiCl₄ molecules are easily separated and become a high degree of dissociation state. Thus, etching is dominant as a large amount of etchant, such as CI ions constituting active species having an etching effect, was generated from the SiCl₄ molecules, and thus a silicon oxide film could not be deposited. Accordingly, until now, the SiCl₄ gas was not used as a film-forming material of plasma CVD executed on an industrial scale.

The plasma CVD apparatus 100 used in the method of the present invention was able to form plasma having a low electron temperature via a configuration of generating plasma by introducing microwaves into the processing container 1 by using the planar is antenna 31 having a plurality of slots (the microwave radiation holes 32). Thus, energy of plasma is low even if the SiCl₄ gas is used as a film-forming material since the plasma CVD apparatus 100 controls a process pressure and a flow of the process gas to be within the above ranges. Accordingly, a amount of SiCl₄ gas of which dissociation stops at SiCl₂ and SiCl₃ state, is large, thereby maintaining a low degree of dissociation state, and thus film-formation becomes dominant. In other words, dissociation of SiCl₄ molecules is suppressed and stops at the steps of i) or ii) by plasma having a low electron temperature and low energy, thereby suppressing formation of the etchant (Cl ions or the like) that adversely affects film-formation, and thus the film-formation becomes dominant.

Since the plasma generated by the method of the present invention has a low electron temperature and a high concentration of electron density, dissociation of the SiCl₄ gas is easy, a lot of SiCl₂ ions are generated, and even an oxygen gas (O₂) having high bonding energy is dissociated in high concentration plasma to become O ions. Also, it is thought that SiO₂ is generated as SiCl₂ ions and O ions react with each other. Accordingly, by using the oxygen gas (O₂), it is possible to form a silicon oxide film. Accordingly, it was possible to form a high quality silicon oxide film having an extremely low hydrogen amount and a reduced ion damage in film by using plasma CVD in which the SiCl₄ gas is used as a material.

Also, since the plasma CVD apparatus 100 dissociates the process gas by using mild plasma having a low electron temperature, a deposition speed (film-forming rate) of a silicon oxide film is easily controlled. Accordingly, film-formation may be performed while controlling a film thickness, for example, from a thin film thickness of about 2 nm to a relatively thick film thickness of about 300 nm.

The method of the present invention may be applied to form a silicon oxide film as, for example, a gate insulation film of a MOS-type semiconductor memory device. Accordingly, the MOS type semiconductor memory device having excellent electric characteristics may be manufactured since a gate leak current is low.

(Example Applied to Manufacturing of Semiconductor Memory Device)

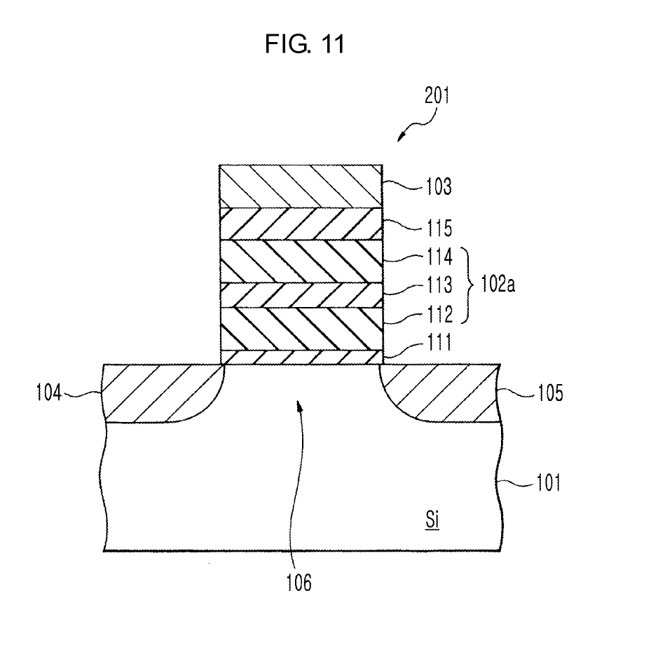

Next, an example of applying the method for forming a silicon oxide film according to the present embodiment to a process of manufacturing a semiconductor memory device will is be described with reference to FIG. 11. FIG. 11 is a cross-sectional view of a schematic configuration of a MOS-type semiconductor memory device 201. The MOS-type semiconductor memory device 201 includes a p-type silicon substrate 101 as a semiconductor layer, a plurality of insulation films stacked on the p-type silicon substrate 101, and a gate electrode 103 additionally formed thereon. A first insulation film 111, a second insulation film 112, a third insulation film 113, a fourth insulation film 114, and a fifth insulation film 115 are formed between the silicon substrate 101 and the gate electrode 103. Here, the second, third, and fourth insulation films 112, 113, and 114 are all silicon nitride films, and form a silicon nitride film stacked body 102a.

Also, in the silicon substrate 101, first source and drain 104 and second source and drain 105 as n-type diffusion layers are formed to be disposed on each side of the gate electrode 103 at a predetermined depth, and a channel forming region 106 is formed therebetween. Also, the MOS-type semiconductor memory device 201 may be formed on a p-well or a p-type silicon layer formed inside a semiconductor substrate. Also, the present embodiment is explained by using an n-channel MOS device as an example, but a p-channel MOS device may be used. Accordingly, descriptions of the present embodiment hereinafter may be applied both to an n-channel MOS device and a p-channel MOS device.

The first insulation film 111, which is a gate insulation film (tunnel insulation film), is a silicon oxide film (SiO₂ film or SiON film) having an extremely low hydrogen concentration below or equal to 9.9×10²⁰ atoms/cm³ in a film formed on a surface of the silicon substrate 101 by using the plasma CVD apparatus 100. A film thickness of the first insulation film 111 is preferably, for example, within the range from 2 nm to 10 nm, and more preferably within the range from 2 nm to 7 nm.

The second insulation film 112 forming the silicon nitride film stacked body 102a is a silicon nitride film (SiN film, here; a composition ratio of Si and N is not definitely determined stoichiometrically, and has different values according to film-forming conditions. The same is applied hereinafter) formed on the first insulation film 111. A film thickness of the second insulation film 112 is preferably, for example, in the range from 2 nm to 20 nm, and more preferably in the range from 3 nm to 5 nm.

The third insulation film 113 is a silicon nitride film (SiN film) formed on the second is insulation film 112. A film thickness of the third insulation film 113 is preferably, for example, in the range from 2 nm to 30 nm, and more preferably in the range from 4 nm to 10 nm.

The fourth insulation film 114 is a silicon nitride film (SiN film) formed on the third insulation film 113. The fourth insulation film 114 may, for example, have the same film thickness as the second insulation film 112.

The fifth insulation film 115 is a silicon oxide film (SiO₂ film) deposited on the fourth insulation film 114, for example, via a CVD method. The fifth insulation film 115 operates as a block layer (barrier layer) between the electrode 103 and the fourth insulation film 114. A film thickness of the fifth insulation film 115 is preferably, for example, in the range from 2 nm to 30 nm, and more preferably in the range from 5 nm to 8 nm.

The gate electrode 103 is, for example, formed of a polycrystalline silicon film formed by a CVD method, and operates as a control gate (CG) electrode. Alternatively, the gate electrode 103 may be a film including a metal such as W, Ti, Ta, Cu, Al, Au, Pt, or the like. The gate electrode 103 is not limited to a single layer, and may have a stacked structure including, for example, tungsten, molybdenum, tantalum, titan, platinum, a silicide thereof, a nitride thereof, an alloy thereof, etc., so as to increase an operating speed of the MOS-type semiconductor memory device 201 by reducing a specific resistance of the gate electrode 103. The gate electrode 103 is connected to a wire layer (not shown).

Also, in the MOS-type semiconductor memory device 201, the silicon nitride film stacked body 102a formed by the second, third, and fourth insulation films 112, 113, and 114 is a charge accumulating region that mainly accumulates charges.

The example of applying the method of the present invention to the manufacturing of the MOS-type semiconductor memory device 201 will be described by using main procedures as an example. First, the silicon substrate 101 on which an isolation film (not shown) is formed using a method such as a LOCOS (Local Oxidation of Silicon) method or an STI (Shallow Trench Isolation) method is prepared, and an SiO₂ film or an SiON film is formed as the first insulation film 111 on a surface of the silicon substrate 101 according to the method of the present invention. In other words, an SiO₂ film or an SiON film having an extremely low hydrogen concentration below or equal to 9.9×10²⁰ atoms/cm³ is deposited on the silicon substrate 101 by performing plasma CVD using SiCl₄ or Si₂H₆, and an oxygen containing gas (for example O₂), and additionally a nitrogen containing gas (for example N₂), if required, as process gases in the plasma CVD apparatus 100.

Then, the second, third, and fourth insulation films 112, 113, and 114 are sequentially formed on the first insulation film 111, for example, by using a CVD method.

Next, the fifth insulation film 115 is formed on the fourth insulation film 114. The fifth insulation film 115 may be formed, for example, by using a CVD method. Also, a metal film as the gate electrode 103 is formed on the fifth insulation film 115, by forming a polysilicon layer, a metal layer, a metal silicide layer, or the like by using, for example, a CVD method.

Then, the metal film and the fifth through first insulation films 115 through 111 are etched by using a patterned resist as a mask via a photolithography technology, thereby obtaining a gate stacked structure having the patterned gate electrode 103 and the plurality of insulation films. Next, a high concentration of n-type impurities are ion-injected into a silicon surface adjacent to both sides of the gate stacked structure, thereby forming the first source and drain 104 and the second source and drain 105. As such, the MOS-type semiconductor memory device 201 having the structure of FIG. 11 may be manufactured. The MOS-type semiconductor memory device 201 manufactured by using the high quality SiO₂ film or the high quality SiON film as the first insulation film 111 is very reliable, and thus is stably operable.

Also in FIG. 11, the silicon nitride film stacked body 102a is formed of three layers, i.e., the second through fourth insulation films 112 through 114, but the method of the present invention may also be applied to cases of manufacturing an MOS-type semiconductor memory device having a silicon nitride film structure in which two or four or more silicon nitride films are stacked.

The embodiments of the present invention have been described above, but the present invention is not limited to the above embodiments, and may vary. For example, the silicon oxide film formed by the method of the present invention may be used, for example, as a gate insulation film, an interlayer insulation film, a liner around a gate, or the like of a transistor, aside from a gate insulation film of an MOS-type semiconductor memory device.

1. A method for forming a silicon oxide film that has an etching rate below or equal to 0.11 nm/s when a 0.5% dilute hydrofluoric acid solution is used, on a substrate by a plasma CVD method, the method comprising:
disposing the substrate in a processing container;
supplying a process gas including a silicon containing gas and an oxygen containing gas into the processing container;
setting an inside pressure of the processing container in a range from 0.1 Pa to 6.7 Pa; and
generating a plasma of the process gas by introducing microwaves into the processing container through a planar antenna having a plurality of slots, and forming the silicon oxide film on the substrate by using the plasma.

2. The method of claim 1, wherein the forming of the silicon oxide film is performed by setting a temperature of a holding stage on which the substrate is placed in the processing container to be within a range from 300° C. to 600° C.

3. The method of claim 1, wherein a flow ratio of the silicon containing gas to the entire process gas is within a range from 0.03% to 15%.

4. The method of claim 3, wherein a flow of the silicon containing gas is within a range from 0.5 mL/min (sccm) to 10 mL/min (sccm).

5. The method of claim 1, wherein a flow ratio of the oxygen containing gas to the entire process gas is within a range from 5% to 99%.

6. The method of claim 5, wherein a flow of the oxygen containing gas is within a range from 50 mL/min (sccm) to 1000 mL/min (sccm).

7. The method of claim 1, wherein the process gas further includes a nitrogen containing gas, and the formed silicon oxide film is a silicon oxynitride film containing nitrogen.

8. The method of claim 7, wherein a flow ratio of the nitrogen containing gas to the entire process gas is within a range from 5% to 99%.

9. The method of claim 8, wherein a flow of the nitrogen containing gas is within a range from 60 mL/min (sccm) to 1000 mL/min (sccm).

10. The method of claim 1, wherein the silicon containing gas is SiCl₄, and a concentration of hydrogen atoms in the silicon oxide film measured by secondary ion mass spectrometry (SIMS) is below or equal to 9.9×10²⁰ atoms/cm³.

11. A silicon oxide film formed by using the method of claim 1.

12. A plasma CVD apparatus for forming a silicon oxide film on a target object by using a plasma CVD method, the plasma CVD apparatus comprising:
a processing container which accommodates a target object and has an opening on a top thereof;
a dielectric member which closes the opening of the processing container;
a planar antenna which is provided to overlap on the dielectric member and has a plurality of holes for introducing microwaves into the processing container;
a gas introduction unit which is connected to a gas supply mechanism for supplying a process gas including a silicon containing gas and an oxygen containing gas into the processing container;
an exhaust mechanism which depressurizes and exhausts an inside of the processing container; and
a control unit which controls plasma CVD to set a inside pressure of the processing container within a range from 0.1 Pa to 6.7 Pa, to supply the process gas including the silicon containing gas and the oxygen containing gas from the gas supply mechanism into the processing container, to generate a plasma by introducing microwaves through the planar antenna, and to form the silicon oxide film having an etching rate below or equal to 0.11 nm/s on the target object when a dilute hydrofluoric acid solution is used.
